(19) United States
(12) Patent Application Publication
(10) Pub. No.: US 2020/0182233 A1
(43) Pub. Date: Jun. 11, 2020

(54) MICRO-ELECTROMECHANICAL SYSTEM PUMP MODULE

(71) Applicant: Microjet Technology Co., Ltd., Hsinchu (TW)

(72) Inventors: Hao-Jan Mou, Hsinchu (TW); Rong-Ho Yu, Hsinchu (TW); Cheng-Ming Chang, Hsinchu (TW); Hsien-Chung Tai, Hsinchu (TW); Wen-Hsiung Liao, Hsinchu (TW); Chi-Feng Huang, Hsinchu (TW); Yung-Lung Han, Hsinchu (TW); Chun-Yi Kuo, Hsinchu (TW)

(73) Assignee: Microjet Technology Co., Ltd., Hsinchu (TW)

(21) Appl. No.: 16/689,755

(22) Filed: Nov. 20, 2019

(30) Foreign Application Priority Data
Dec. 5, 2018 (TW) 107143737

(51) Int. Cl. F04B 43/04; B81B 7/00

(52) U.S. Cl. CPC F04B 43/046; B81B 2201/036; B81B 7/0006

(57) ABSTRACT

A MEMS pump module includes a microprocessor and a MEMS chip. The microprocessor outputs a constant voltage and a variable voltage. The MEMS chip includes a chip body, a plurality of MEMS pumps and at least one common electrode. The plurality of MEMS pumps are disposed on the chip body, and each MEMS pump includes a first electrode and a second electrode. The at least one common electrode is disposed on the chip body and electrically connected to the second electrodes of the plurality of MEMS pumps. The microprocessor is electrically connected to the first electrodes of the plurality of MEMS pumps and the at least one common electrode so as to transmit the constant voltage to the at least one common electrode and transmit the variable voltage to the first electrodes of the plurality of MEMS pumps.

### FIELD OF THE INVENTION

The present disclosure relates to a micro-electromechanical system (MEMS) pump module, and more particularly to a MEMS pump module having at least one common electrode to reduce the number of contacts of a microprocessor and further simplify the contacts and the routing and layout of the MEMS pumps.

### BACKGROUND OF THE INVENTION

With the rapid development of technology, the applications of fluid transportation devices are becoming more and more diversified. For example, fluid transportation devices are gradually popular in industrial applications, biomedical applications, medical care applications, heat dissipation applications, or even the wearable devices. Regarding fluid transportation devices, it is obvious that the current trend is towards miniaturization in design. As known, it is difficult to reduce the size of the conventional pump to the millimeter scale. Consequently, the conventional miniature fluid transportation device uses a piezoelectric pump structure to transport fluid.

Generally, the size of a MEMS pump may be minimized to the nanoscale. However, since the volume of the MEMS pump is very small, the amount of fluid to be transported by the MEMS pump is limited. Consequently, a plurality of MEMS pumps are collaboratively operated to transport the fluid. FIG. 1 schematically illustrates a conventional MEMS pump module. As shown in FIG. 1, the MEMS pump module includes a high-level microprocessor 1 to control respective MEMS pumps 2. However, the cost of the high-level microprocessor 1 is high. In addition, each MEMS pump 2 is electrically connected to two pins 11 of the high-level microprocessor 1. That is, the pin number of the high-level microprocessor 1 is very large. Since the cost of the high-level microprocessor 1 is further increased, it is difficult to reduce the cost of the MEMS pump module. Consequently, the MEMS pump module is hard to be widely used owing to its high cost. Therefore, there is a need of providing a MEMS pump module for reducing the cost in actuation of MEMS devices.

### SUMMARY OF THE INVENTION

An object of the present disclosure provides a MEMS pump module. The MEMS pump module has at least one common electrode to reduce the number of contacts of the microprocessor, reduce the contacts and routing and layout of the MEMS pump and further simplify the structure of the MEMS pump module.

In accordance with an aspect of the present disclosure, a MEMS pump module is provided. The MEMS pump module includes a microprocessor and a MEMS chip. The microprocessor outputs a constant voltage and a variable voltage. The MEMS chip is electrically connected to the microprocessor. The MEMS chip includes a chip body, a plurality of MEMS pumps and at least one common electrode. The plurality of MEMS pumps are disposed on the chip body, and each of the plurality of MEMS pumps includes a first electrode and a second electrode. The at least one common electrode is disposed on the chip body and electrically connected to the second electrodes of the plurality of MEMS pumps. The microprocessor is electrically connected to the first electrodes of the plurality of MEMS pumps and the at least one common electrode so as to transmit the constant voltage to the at least one common electrode and transmit the variable voltage to the first electrodes of the plurality of MEMS pumps.

The above contents of the present disclosure will become more readily apparent to those ordinarily skilled in the art after reviewing the following detailed description and accompanying drawings, in which:

### BRIEF DESCRIPTION OF THE DRAWINGS

FIG. 1 schematically illustrates a conventional MEMS pump module;

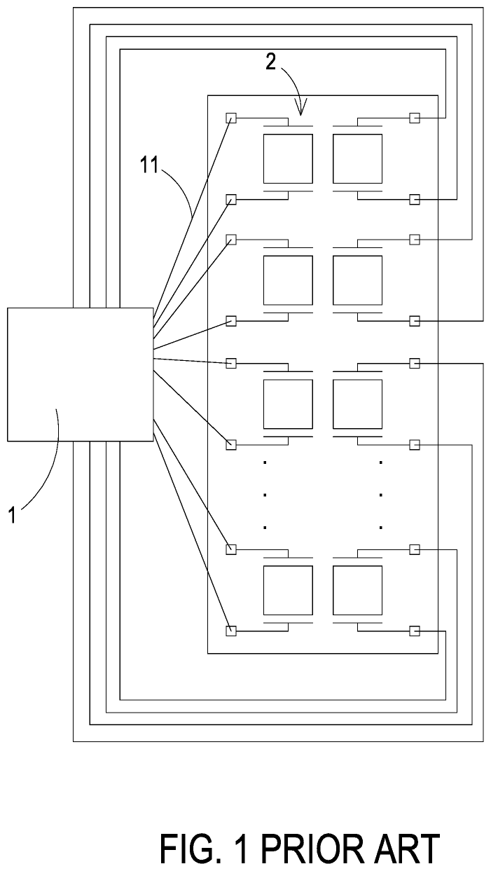

FIG. 2 schematically illustrates a MEMS pump module according to a first embodiment of the present disclosure;

FIG. 3 schematically illustrates a MEMS chip of a MEMS pump module according to a second embodiment of the present disclosure;

FIG. 4 schematically illustrates a MEMS chip of a MEMS pump module according to a third embodiment of the present disclosure;

FIG. 5 schematically illustrates a MEMS chip of a MEMS pump module according to a fourth embodiment of the present disclosure;

FIG. 6 schematically illustrates a MEMS chip of a MEMS pump module according to a fifth embodiment of the present disclosure;

FIG. 7 schematically illustrates a MEMS chip of a MEMS pump module according to a sixth embodiment of the present disclosure;

FIG. 8A is a schematic circuit illustrating the relationship between the MEMS pump and the common electrode of the MEMS chip according to the present disclosure;

FIG. 8B is a schematic timing waveform diagram illustrating a first exemplary control signal from the microprocessor of the MEMS pump module according to the present disclosure;

FIG. 8C is a schematic timing waveform diagram illustrating a second exemplary control signal from the microprocessor of the MEMS pump module according to the present disclosure; and

FIG. 8D is a schematic timing waveform diagram illustrating a third exemplary control signal from the microprocessor of the MEMS pump module according to the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

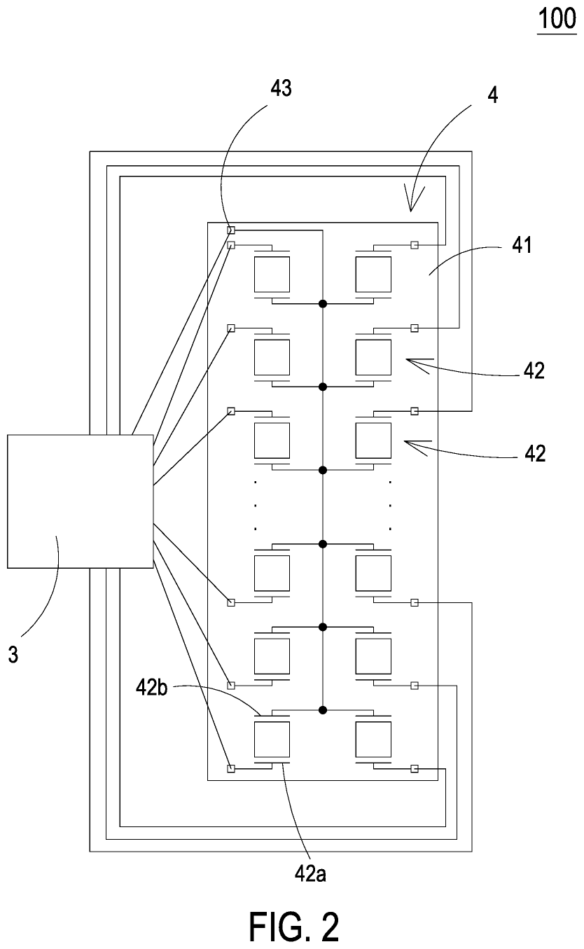

Please refer to FIG. 2. The present discourse provides a MEMS pump module 100 including at least one microprocessor 3, at least one constant voltage, at least one variable voltage, at least one MEMS chip 4, at least one chip body 41, at least one first electrode 42a and at least one second electrode 42b. The number of the microprocessor 3, the constant voltage, the variable voltage, the MEMS chip 4, the chip body 41, the first electrode 42a and the second electrode 42b is exemplified by one for each in the following embodiments but not limited thereto. It is noted that each of the microprocessor 3, the constant voltage, the variable voltage, the MEMS chip 4, the chip body 41, the first electrode 42a and the second electrode 42b can also be provided in plural numbers.

FIG. 2 schematically illustrates a MEMS pump module according to a first embodiment of the present disclosure. The MEMS pump module 100 includes a microprocessor 3 and a MEMS chip 4. The MEMS chip 4 is electrically connected to the microprocessor 3. In this embodiment, the MEMS chip 4 includes a chip body 41, a plurality of MEMS pumps 42 and at least one common electrode 43. The plurality of MEMS pumps 42 are disposed on the chip body 41, and each MEMS pump 42 includes a first electrode 42a and a second electrode 42b. The at least one common electrode 43 is disposed on the chip body 41 and electrically connected to all of the second electrodes 42b of the MEMS pumps 42. Moreover, all of the first electrodes 42a of the MEMS pumps 42 and the at least one common electrode 43 disposed on the chip body 41 are electrically connected to the microprocessor 3 to receive control signals from the microprocessor 3.

Please refer to FIG. 2 again. In this embodiment, the MEMS chip 4 includes one common electrode 43. That is, the number of the at least one common electrode 43 is one. Moreover, the second electrodes 42b of all MEMS pumps 42 are electrically connected to the common electrode 43.

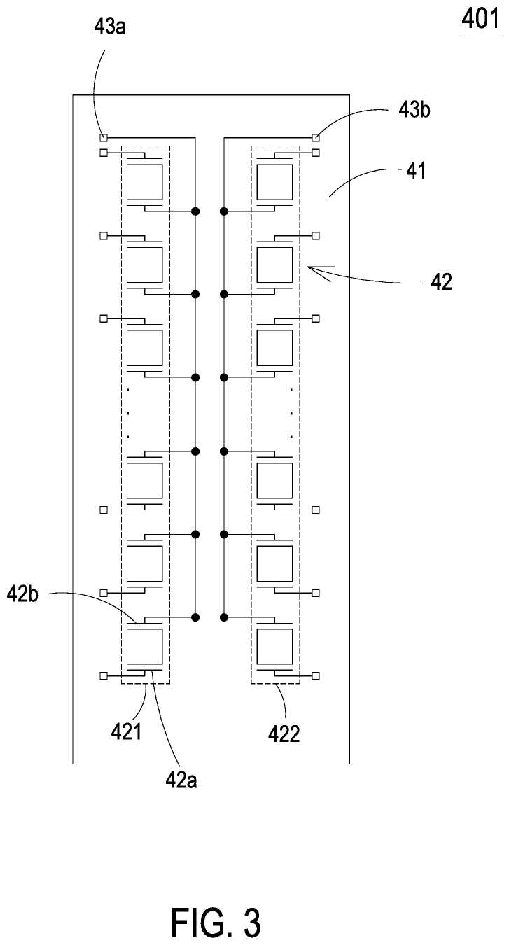

Please refer to FIG. 3, which schematically illustrates a MEMS chip of a MEMS pump module according to a second embodiment of the present disclosure. In this embodiment, the MEMS chip 401 includes a first common electrode 43a and a second common electrode 43b. According to the positions, the plurality of MEMS pumps 42 are classified into a first MEMS pump group 421 and a second MEMS pump group 422. That is, the plurality of MEMS pumps 42 consist of the first MEMS pump group 421 and the second MEMS pump group 422. The second electrodes 42b of the MEMS pumps 42 in the first MEMS pump group 421 are electrically connected to the first common electrode 43a. The second electrodes 42b of the MEMS pumps 42 in the second MEMS pump group 422 are electrically connected to the second common electrode 43b. Consequently, the partition control purpose is achieved. That is, both the first MEMS pump group 421 and the second MEMS pump group 422 can be controlled independently. In this embodiment, the number of the at least one common electrode is two.

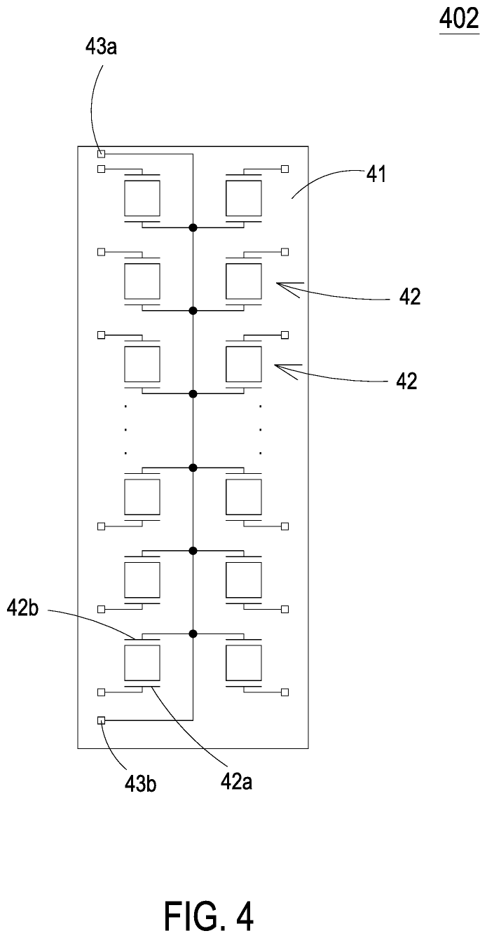

Please refer to FIG. 4, which schematically illustrates a MEMS chip of a MEMS pump module according to a third embodiment of the present disclosure. Like the second embodiment, the number of the at least one common electrode is two. The MEMS chip 402 includes a first common electrode 43a and a second common electrode 43b. The chip body 41 has a first side and a second side opposite to the first side. The first common electrode 43a and the second common electrode 43b are disposed on the first side and the second side of the chip body 41, respectively. Moreover, the first common electrode 43a and the second common electrode 43b are electrically connected to each other. The second electrodes 42b of the plurality of MEMS pumps 42 are electrically connected to both of the first common electrode 43a and the second common electrode 43b, which are disposed on the first side and the second side of the chip body 41 respectively. The design of this embodiment can reduce the impedance between the second electrodes 42b of the plurality of MEMS pumps 42 and the common electrodes 43a or 43b. Consequently, the power loss of the second electrodes 42b at the positions away from the common electrodes 43a or 43b will be reduced.

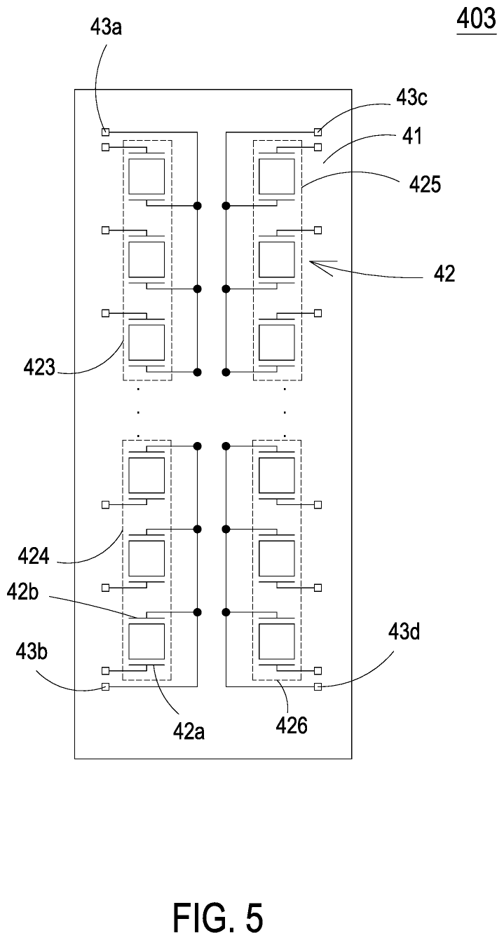

Please refer to FIG. 5, which schematically illustrates a MEMS chip of a MEMS pump module according to a fourth embodiment of the present disclosure. In this embodiment, the MEMS chip 403 includes a first common electrode 43a, a second common electrode 43b, a third common electrode 43c and a fourth common electrode 43d. The chip body 41 has a first side and a second side opposite to the first side. The first common electrode 43a and the third common electrode 43c are disposed on the first side of the chip body 41 and separated from each other. The second common electrode 43b and the fourth common electrode 43d are disposed on the second side of the chip body 41 and separated from each other. According to the positions, the plurality of MEMS pumps 42 are classified into a first MEMS pump group 423, a second MEMS pump group 424, a third MEMS pump group 425 and a fourth MEMS pump group 426. That is, the plurality of MEMS pumps 42 consist of the first MEMS pump group 423, the second MEMS pump group 424, the third MEMS pump group 425 and the fourth MEMS pump group 426. The first MEMS pump group 423 consists of one or more MEMS pumps 42 that are disposed adjacent to the first common electrode 43a. The second electrodes 42b of the MEMS pumps 42 in the first MEMS pump group 423 are electrically connected to the first common electrode 43a. The second MEMS pump group 424 consists of one or more MEMS pumps 42 that are disposed adjacent to the second common electrode 43b. The second electrodes 42b of the MEMS pumps 42 in the second MEMS pump group 422 are electrically connected to the second common electrode 43b. The third MEMS pump group 425 consists of one or more MEMS pumps 42 that are disposed adjacent to the third common electrode 43c. The second electrodes 42b of the MEMS pumps 42 in the third MEMS pump group 425 are electrically connected to the third common electrode 43c. The fourth MEMS pump group 426 consists of one or more MEMS pumps 42 that are disposed adjacent to the fourth common electrode 43d. The second electrodes 42b of the MEMS pumps 42 in the fourth MEMS pump group 426 are electrically connected to the fourth common electrode 43d. Consequently, the partition control purpose is achieved. That is, the first MEMS pump group 423, the second MEMS pump group 424, the third MEMS pump group 425, and the fourth MEMS pump group 426 can be controlled independently.

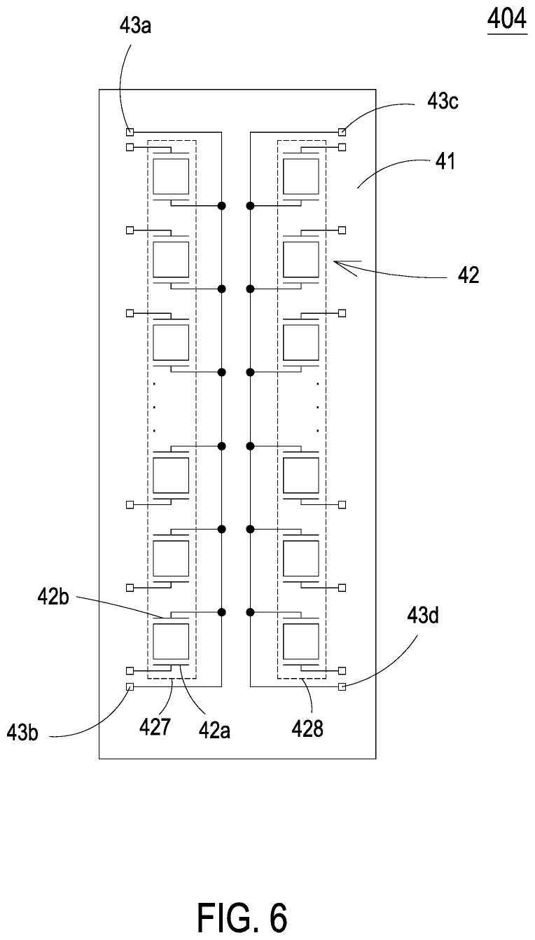

Please refer to FIG. 6, which schematically illustrates a MEMS chip of a MEMS pump module according to a fifth embodiment of the present disclosure. Like the fourth embodiment, the MEMS chip 404 includes a first common electrode 43a, a second common electrode 43b, a third common electrode 43c and a fourth common electrode 43d. The locations of these common electrodes 43a, 43b, 43c and 43d are identical to those of the fourth embodiment. However, the connecting relationships of the common electrodes 43a, 43b, 43c and 43d and the grouping of the MEMS pumps 42 of the fifth embodiment are different from that of the fourth embodiment. In this embodiment, the first common electrode 43a and the second common electrode 43b are electrically connected to each other, and the third common electrode 43c and the fourth common electrode 43d are electrically connected to each other. The plurality of MEMS pumps 42 are classified into a first MEMS pump group 427 and a second MEMS pump group 428. That is, the plurality of MEMS pumps 42 consist of the first MEMS pump group 427 and the second MEMS pump group 428. The first MEMS pump group 427 consists of one or more MEMS pumps 42 that are disposed adjacent to the first common electrode 43a or the second common electrode 43b. The second MEMS pump group 428 consists of one or more MEMS pumps 42 that are disposed adjacent to third common electrode 43c or the fourth common electrode 43d. The second electrodes 42b of the plurality of MEMS pumps 42 in first MEMS pump group 427 are electrically connected to both of the first common electrode 43a and the second common electrode 43b. The second electrodes 42b of the plurality of MEMS pumps 42 in second MEMS pump group 428 are electrically connected to both of the third common electrode 43c and the fourth common electrode 43d. Consequently, the partition control purpose is achieved. That is, both the first MEMS pump group 427 and the second MEMS pump group 428 can be controlled independently. Moreover, since the distances among the common electrodes (i.e., 43a, 43b, 43c, and 43d) and the second electrodes 42b are shortened, the power transmission loss is reduced.

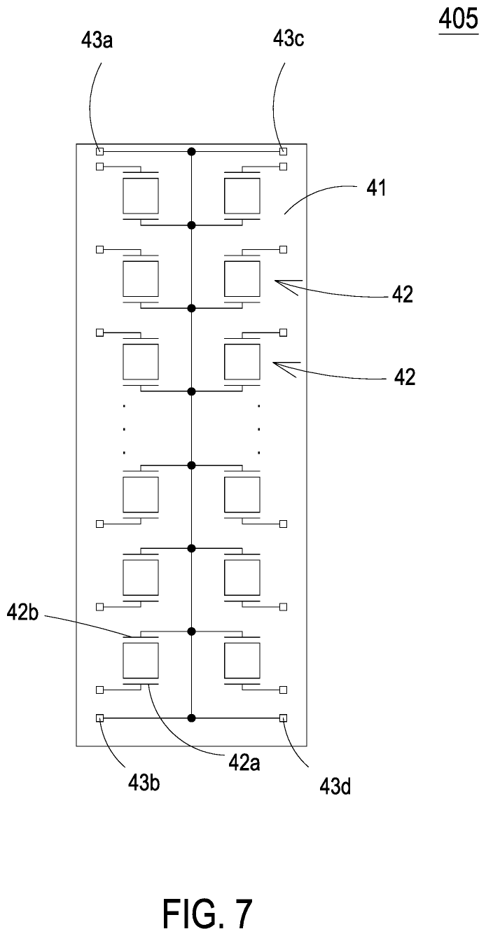

Please refer to FIG. 7, which schematically illustrates a MEMS chip of a MEMS pump module according to a sixth embodiment of the present disclosure. Like the fourth embodiment, the MEMS chip 405 includes a first common electrode 43a, a second common electrode 43b, a third common electrode 43c and a fourth common electrode 43d. The locations of these common electrodes 43a, 43b, 43c, and 43d are identical to those of the fourth embodiment. However, the connecting relationships of the common electrodes 43a, 43b, 43c, and 43d and the grouping of the MEMS pumps 42 of the sixth embodiment are different from that of the fourth embodiment. In this embodiment, the first common electrode 43a, the second common electrode 43b, the third common electrode 43c and the fourth common electrode 43d are electrically connected with each other. Consequently, the second electrodes 42b of the MEMS pumps 42 are electrically connected to the nearby common electrodes 43a, 43b, 43c, and 43d. For example, the second electrodes 42b of the MEMS pumps 42 near the first common electrode 43a are electrically connected to the first common electrode 43a. The second electrodes 42b of the MEMS pumps 42 near the second common electrode 43b are electrically connected to the second common electrode 43b. The second electrodes 42b of the MEMS pumps 42 near the third common electrode 43c are electrically connected to the third common electrode 43c. The second electrodes 42b of the MEMS pumps 42 near the fourth common electrode 43d are electrically connected to the fourth common electrode 43d. Since the distances among the common electrodes (i.e., 43a, 43b, 43c, and 43d) and the second electrodes 42b are shortened, the power transmission loss is reduced.

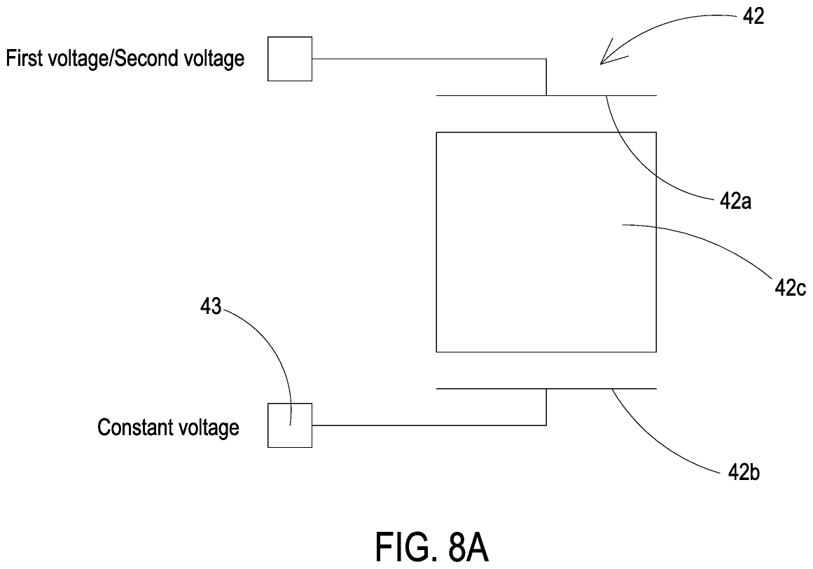

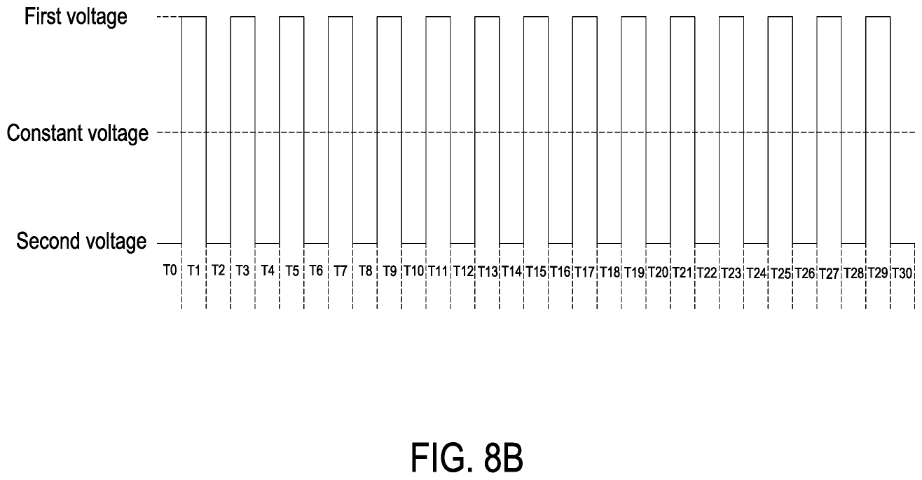

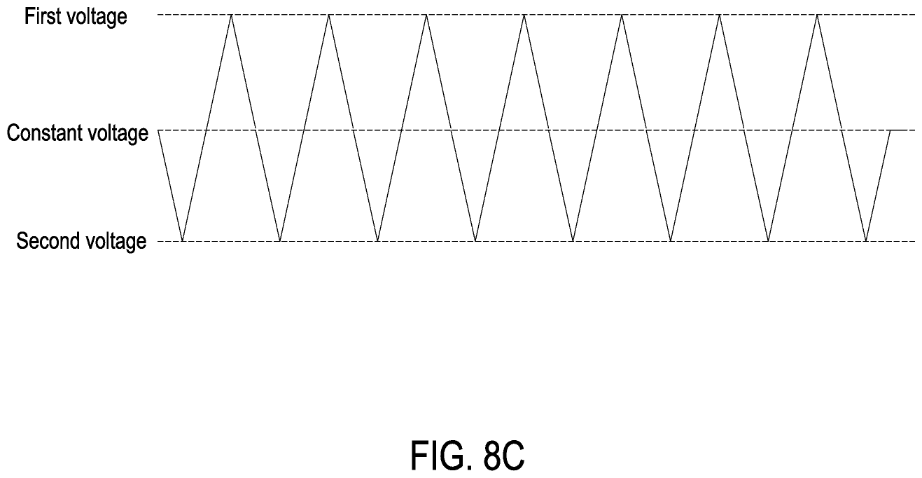

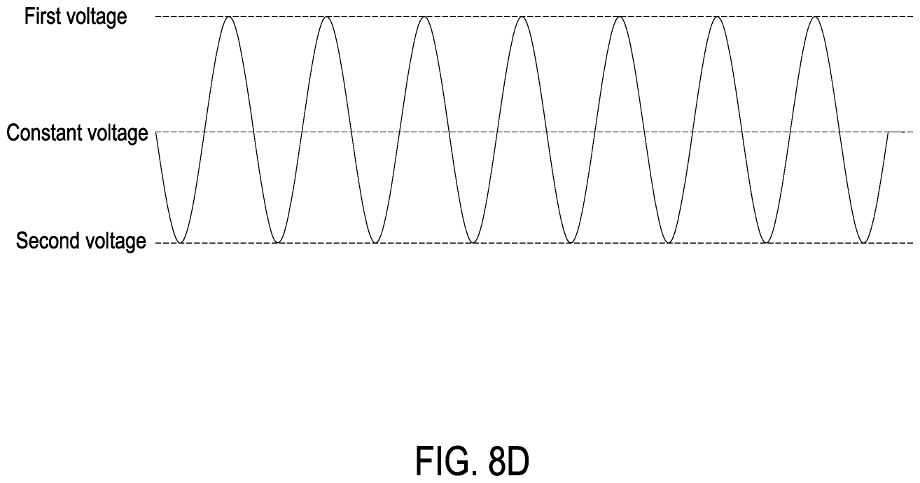

Please refer to FIGS. 2, 8A and 8B. FIG. 8A is a schematic circuit illustrating the relationship between the MEMS pump and the common electrode of the MEMS chip according to the present disclosure. FIG. 8B is a schematic timing waveform diagram illustrating a first exemplary control signal from the microprocessor of the MEMS pump module according to the present disclosure. In this embodiment, the MEMS pump 42 further includes a piezoelectric element 42c. When the voltages are transmitted from the microprocessor 3 through the first electrode 42a and the second electrode 42b to the piezoelectric element 42c, the piezoelectric element 42c is subjected to deformation due to piezoelectric effect, so that the pressure in the interior of the MEMS pump 42 is correspondingly changed to transport the fluid. The first electrode 42a of the MEMS pump 42 is electrically connected to the microprocessor 3, as shown in FIG. 2. The second electrode 42b of the MEMS pump 42 is electrically connected to the microprocessor 3 through the common electrode 43, again as shown in FIG. 2. The control signal outputted from the microprocessor 3 contains a constant voltage and a variable voltage. In this embodiment, the variable voltage is alternately switched between the first voltage and the second voltage. The magnitude of the constant voltage is in the range between the first voltage and the second voltage. In an embodiment, the magnitude of the constant voltage is equal to the average of the first voltage and the second voltage (or ranges between ±10% of the average of the first voltage and the second voltage). The magnitude of the constant voltage ranges between ±10% of the average of the first voltage and the second voltage, means that the magnitude of the constant voltage may range between 110% and 90% of the average of the first voltage and the second voltage. In an example, the first voltage, the second voltage and the constant voltage are 1.5V, −1.5V and 0V, respectively. In another example, the first voltage, the second voltage and the constant voltage are 3V, 0V and 1.5V, respectively. Consequently, the second electrode 42b of the MEMS pump 42 receives the constant voltage, and the first electrode 42a of the MEMS pump 42 receives the variable voltage alternately switched between the first voltage and the second voltage. Due to the alternately-switched voltage difference between the first electrode 42a and the second electrode 42b, the piezoelectric element 42c is subjected to reciprocating deformation to transport the fluid.

It is noted that the waveform of the control signal is not restricted. Please refer to FIGS. 8C and 8D. FIG. 8C is a schematic timing waveform diagram illustrating a second exemplary control signal from the microprocessor of the MEMS pump module according to the present disclosure. FIG. 8D is a schematic timing waveform diagram illustrating a third exemplary control signal from the microprocessor of the MEMS pump module according to the present disclosure. Similarly, the variable voltage is alternately switched between the first voltage and the second voltage. In the example of FIG. 8B, the variable voltage has a waveform of a square wave. Alternatively, the variable voltage of the control signal has a waveform of a triangular wave (see FIG. 8C) or a sinusoidal wave (see FIG. 8D).

From the above descriptions, the present disclosure provides the MEMS pump module. The microprocessor transmits the constant voltage through the at least one common electrode to the second electrodes of the MEMS pumps. In addition, the microprocessor transmits the variable voltage to the first electrodes of the MEMS pumps. By adjusting the voltage applied to the first electrode, the voltage difference between the first electrode and the corresponding second electrode is changed, so that the piezoelectric element of the MEMS pump module is driven to transport the fluid. Moreover, due to the arrangement of the at least one common electrode, the number of pins of the microprocessor is largely reduced and the cost of the microprocessor is reduced. Under this circumstance, the plurality of MEMS pumps can still be effectively controlled.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A micro-electromechanical system (MEMS) pump module, comprising:
a microprocessor outputting a constant voltage and a variable voltage; and
a MEMS chip electrically connected to the microprocessor, and comprising:
a chip body;
a plurality of MEMS pumps disposed on the chip body, wherein each of the plurality of MEMS pumps comprises a first electrode and a second electrode; and
at least one common electrode disposed on the chip body and electrically connected to the second electrodes of the plurality of MEMS pumps,
wherein the microprocessor is electrically connected to the first electrodes of the plurality of MEMS pumps and the at least one common electrode so as to transmit the constant voltage to the at least one common electrode and transmit the variable voltage to the first electrodes of the plurality of MEMS pumps.

2. The MEMS pump module according to claim 1, wherein the at least one common electrode includes a first common electrode.

3. The MEMS pump module according to claim 2, wherein the second electrodes of the plurality of MEMS pumps are electrically connected to the first common electrode.

4. The MEMS pump module according to claim 2, wherein the at least one common electrode further includes a second common electrode.

5. The MEMS pump module according to claim 4, wherein the plurality of MEMS pumps are classified into a first MEMS pump group and a second MEMS pump group, wherein the second electrodes of the MEMS pumps in the first MEMS pump group are electrically connected to the first common electrode, and the second electrodes of the MEMS pumps in the second MEMS pump group are electrically connected to the second common electrode.

6. The MEMS pump module according to claim 4, wherein the second electrodes of the plurality of MEMS pumps are electrically connected to the first common electrode and the second common electrode.

7. The MEMS pump module according to claim 4, wherein the at least one common electrode further includes a third common electrode and a fourth common electrode.

8. The MEMS pump module according to claim 7, wherein the plurality of MEMS pumps are classified into a first MEMS pump group, a second MEMS pump group, a third MEMS pump group and a fourth MEMS pump group, wherein the second electrodes of the MEMS pumps in the first MEMS pump group are electrically connected to the first common electrode, the second electrodes of the MEMS pumps in the second MEMS pump group are electrically connected to the second common electrode, the second electrodes of the MEMS pumps in the third MEMS pump group are electrically connected to the third common electrode, and the second electrodes of the MEMS pumps in the fourth MEMS pump group are electrically connected to the fourth common electrode.

9. The MEMS pump module according to claim 7, wherein the plurality of MEMS pumps are classified into a first MEMS pump group and a second MEMS pump group, wherein the second electrodes of the MEMS pumps in the first MEMS pump group are electrically connected to the first common electrode and the second common electrode, and the second electrodes of the MEMS pumps in the second MEMS pump group are electrically connected to the third common electrode and the fourth common electrode.

10. The MEMS pump module according to claim 7, wherein the second electrodes of the plurality of MEMS pumps are electrically connected to the first common electrode, the second common electrode, the third common electrode and the fourth common electrode.

11. The MEMS pump module according to claim 1, wherein the variable voltage comprises a first voltage and a second voltage, and the constant voltage is in the range between the first voltage and the second voltage.

12. The MEMS pump module according to claim 11, wherein the constant voltage ranges between ±10% of an average of the first voltage and the second voltage.

13. The MEMS pump module according to claim 11, wherein the constant voltage is equal to an average of the first voltage and the second voltage.

14. A micro-electromechanical system (MEMS) pump module, comprising:
at least one microprocessor outputting at least one constant voltage and at least one variable voltage; and
at least one MEMS chip electrically connected to the microprocessor, and comprising:
at least one chip body;
a plurality of MEMS pumps disposed on the chip body, wherein each of the plurality of MEMS pumps comprises at least one first electrode and at least one second electrode; and
at least one common electrode disposed on the chip body and electrically connected to the second electrodes of the plurality of MEMS pumps,
wherein the microprocessor is electrically connected to the first electrodes of the plurality of MEMS pumps and the at least one common electrode so as to transmit the constant voltage to the at least one common electrode and transmit the variable voltage to the first electrodes of the plurality of MEMS pumps.
